(19) United States
(12) Patent Application Publication
(10) Pub. No.: US 2012/0318340 A1
(43) Pub. Date: Dec. 20, 2012

(54) BACK JUNCTION SOLAR CELL WITH TUNNEL OXIDE

(75) Inventors: Jiunn Benjamin Heng, San Jose, CA (US); Jianming Fu, Palo Alto, CA (US); Zheng Xu, Pleasanton, CA (US); Zhigang Xie, San Jose, CA (US)

(73) Assignee: SILEVO, INC., Fremont, CA (US)

(21) Appl. No.: 13/601,441

(22) Filed: Aug. 31, 2012

Related U.S. Application Data
(63) Continuation-in-part of application No. 12/945,792, filed on Nov. 12, 2010.
(60) Provisional application No. 61/646,700, filed on May 14, 2012.
(60) Provisional application No. 61/331,158, filed on May 4, 2010.

(51) Int. Cl. H01L 31/0264; H01L 31/18; H01L 31/0368; H01L 31/20; H01L 31/0248; H01L 31/0376

(52) U.S. Cl. 136/255; 136/252; 136/261; 136/258; 438/94; 257/E31.048; 257/E31.044

(57) ABSTRACT

One embodiment of the present invention provides a back junction solar cell. The solar cell includes a base layer, a quantum-tunneling-barrier (QTB) layer situated below the base layer facing away from incident light, an emitter layer situated below the QTB layer, a front surface field (FSF) layer situated above the base layer, a front-side electrode situated above the FSF layer, and a back-side electrode situated below the emitter layer.

### RELATED APPLICATION

This application claims the benefit of U.S. Provisional Application No. 61/646,700, Attorney Docket Number SSP12-1001PSP, entitled “Back Junction Solar Cell with Tunnel Oxide,” by inventors Jiunn Benjamin Heng, Jianming Fu, Zheng Xu, and Zhigang Xie, filed 14 May 2012.

This application is a continuation-in-part application of U.S. patent application Ser. No. 12/945,792 (attorney docket number SSP10-1002US), entitled “Solar Cells with Oxide Tunneling Junctions,” by inventors Jiunn Benjamin Heng, Chentao Yu, Zheng Xu, and Jianming Fu, filed 12 Nov. 2010, which claims the benefit of U.S. Provisional Application No. 61/331,158, Attorney Docket Number SSP10-1002PSP, entitled “Solar Cell with Hetero Tunneling Junction (HTJ),” by inventors Jiunn Benjamin Heng, Chentao Yu, Zheng Xu, and Jianming Fu, filed 4 May 2010.

### BACKGROUND

1. Field

This disclosure is generally related to solar cells. More specifically, this disclosure is related to a solar cell that has a back junction and an oxide tunneling layer.

2. Related Art

The negative environmental impact caused by the use of fossil fuels and their rising cost have resulted in a dire need for cleaner, cheaper alternative energy sources. Among different forms of alternative energy sources, solar power has been favored for its cleanness and wide availability.

A solar cell converts light into electricity using the photoelectric effect. There are many solar cell structures and a typical solar cell contains a p-n junction that includes a p-type doped layer and an n-type doped layer. In addition, there are other types of solar cells that are not based on p-n junctions. For example, a solar cell can be based on a metal-insulator-semiconductor (MIS) structure that includes an ultra-thin dielectric or insulating interfacial tunneling layer situated between a metal or a highly conductive layer and a doped semiconductor layer.

Among various types of solar cells, silicon heterojunction (SHJ) solar cells have drawn attention for their high-efficiency. For example, U.S. Pat. No. 5,705,828 discloses a double-sided heterojunction solar cell, which achieves high efficiency using excellent surface passivation. The key improvement of a double-sided heterojunction solar cell is a higher open circuit voltage (V_{oc}), such as greater than 715 mV (compared with the 600 mV V_{oc} of the conventional crystalline Si based solar cells).

Other approaches to obtain high-efficiency solar cells by improving passivation at the emitter surface have been proposed. U.S. Pat. No. 5,705,828 and U.S. Pat. No. 7,030,413 describe a surface-passivation method that uses an intrinsic semiconductor layer, such as a layer of intrinsic a-Si. The intrinsic a-Si layer can provide excellent passivation for the crystalline Si emitter by lowering the number of surface dangling bonds and reducing the minority carrier concentration. The latter effect is the result of the surface field (formed by the valence band offset), which pushes minority carriers away from the interface and the emitter. However, further improvement is still needed to obtain solar cells with even better performance and greater efficiency.

### SUMMARY

One embodiment of the present invention provides a back junction solar cell. The solar cell includes a base layer, a quantum-tunneling-barrier (QTB) layer situated below the base layer facing away from incident light, an emitter layer situated below the QTB layer, a front surface field (FSF) layer situated above the base layer, a front-side electrode situated above the FSF layer, and a back-side electrode situated below the emitter layer.

In a variation on the embodiment, the base layer includes at least one of: a mono-crystalline silicon wafer, and an epitaxially grown crystalline-Si (c-Si) thin film.

In a further variation, the epitaxially grown c-Si thin film's doping profile is modulated.

In a variation on the embodiment, the QTB layer includes at least one of: silicon oxide (SiOₓ), hydrogenerated SiOₓ, silicon nitride (SiNₓ), hydrogenerated SiNₓ, aluminum oxide (AlOₓ), silicon oxynitride (SiON), and hydrogenerated SiON.

In a variation on the embodiment, the QTB layer has a thickness between 1 and 50 angstroms.

In a variation on the embodiment, the QTB layer is formed using at least one of the following techniques: thermal oxidation, atomic layer deposition, wet or steam oxidation, low-pressure radical oxidation, and plasma-enhanced chemical-vapor deposition (PECVD).

In a variation on the embodiment, the solar cell further includes at least one of: a first transparent conductive oxide (TCO) layer situated below the emitter layer, and a second TCO layer situated above the FSF layer.

In a further variation, the first and second TCO layers comprises at least one of: indium-tin-oxide (ITO), indium oxide (InO), indium-zinc-oxide (IZO), tungsten-doped indium-oxide (IWO), tin-oxide (SnOx), aluminum doped zinc-oxide (ZnO:Al or AZO), and gallium doped zinc-oxide (ZnO:Ga).

In a variation on the embodiment, the emitter and/or the surface field layer include at least one of: amorphous-Si (a-Si), polycrystalline Si, and one or more wide bandgap semiconductor materials.

In a further variation, the emitter and/or the surface field layer comprise a graded-doped amorphous-Si (a-Si) layer with a doping concentration ranging between 1×10¹⁵ /cm³ and 5×10²⁰ /cm³.

In a variation on the embodiment, the solar cell further includes a front QTB layer situated between the FSF layer and the base layer.

### BRIEF DESCRIPTION OF THE FIGURES

FIG. 1A presents a diagram illustrating an exemplary back junction solar cell with tunneling oxide, in accordance with an embodiment of the present invention.

FIG. 1B presents a diagram illustrating the improvement of V_{oc} for the back junction solar cells over the front junction solar cells, in accordance with an embodiment of the present invention.

FIG. 1C presents a diagram illustrating the improvement of FF for the back junction solar cells over the front junction solar cells, in accordance with an embodiment of the present invention.

FIG. 2 presents a diagram illustrating the process of fabricating a back junction solar cell with tunneling oxide, in accordance with an embodiment of the present invention.

FIG. 3 presents a diagram illustrating the process of fabricating a back junction solar cell with tunneling oxide, in accordance with an embodiment of the present invention.

FIG. 4 presents a diagram illustrating the process of fabricating a back junction solar cell with tunneling oxide, in accordance with an embodiment of the present invention.

FIG. 5 presents a diagram illustrating the process of fabricating a back junction solar cell with tunneling oxide, in accordance with an embodiment of the present invention.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the present invention is not limited to the embodiments shown, but is to be accorded the widest scope consistent with the principles and features disclosed herein.

### Overview

Embodiments of the present invention provide a crystalline-Si (c-Si)-based solar cell having its heterojunction at the backside (away from the sunlight). The back junction solar cell further includes a thin dielectric layer functioning as an interface passivation layer as well as a quantum-tunneling barrier (QTB). The solar cell can be fabricated by depositing a high-quality ultra-thin oxide layer, which provide passivation and enables quantum tunneling of carriers, on the front and back surfaces of a c-Si substrate. Subsequently, a hydrogenated graded-doping amorphous-Si (a-Si) layer having an opposite conductive doping type of that of the c-Si substrate is deposited on the back oxide layer to form the solar cell emitter. Another layer of hydrogenated a-Si having the same conductive doping type of that of the c-Si substrate is deposited on the front oxide layer to form a front surface-field layer that passivates the front surface.

### Back Junction Solar Cell

To obtain a double-sided heterojunction solar cell with an even better performance (such as an efficiency of greater than 20%), tunneling oxide layers have been used to enable very low (lower than 1×10¹¹/cm²) defect interface states (Dit), and to further block the flow of minority carriers across the interfaces. The resulted solar cell has a very high open circuit voltage (V_{oc}), which can be greater than 725 mV. A high V_{oc} is crucial for a high-performance solar cell with low (lower than 0.25%/C°) temperature coefficient. Other advanced material growth and preparation methods can also be used to further reduce the surface recombination velocity. For example, it has been reported that atomic layer silicon oxide can reduce the surface trap density to around 1×10¹/cm².

The conventional heterojunction solar cells often have the so-called front junction structure, meaning the p-n junction of the solar cells are located at the front side, the side that faces the sunlight, of the solar cells. There are several inherent deficiencies associated with such a front junction structure that limits the solar cell performance. First, because the solar cell substrates are often n-type doped, the emitter layers need to be p-type doped. The p-type doped emitter layer (or the boron-doped Si layer) often has a high defect density, resulting in a higher recombination rate of generated excess carriers, which translates to a reduced solar cell current. To mitigate such a carrier loss, in practice, these solar cells often have a relatively thin emitter layer or an emitter layer with a low dopant activation rate. For example, the thickness of the emitter layer of a typical front junction solar cell is between 4 and 6 nm. This can result in the emitter layer being partially depleted because the emitter layer is sandwiched between a TCO layer (normally n-type doped) and an intrinsic a-Si or dielectric layer. This partially depleted, p-type doped emitter layer makes it harder to achieve optimal work function matching between the emitter and the front TCO layer. A TCO layer with high work function may be needed.

Moreover, because the emitter is on the light-facing side of the solar cell, the region near the light-facing surface tends to have a higher carrier density, which can result in increased junction recombination of the generated excess carriers. In addition, the p-type doped emitter can have a degradation that is similar to the light-induced degradation (LID) because more active boron dopants are facing the sunlight.

To overcome these deficiencies, embodiments of the present invention provide an ultra-high performance solar cell that has a back junction structure and an oxide tunneling layer. The back junction solar cell has its emitter located at the side that faces away from the incoming sunlight, thus minimizing the loss of current due to short wavelength absorption, which occurs near the front surface of the solar cell. In addition, while located at the backside, facing away from the sunlight, the p-typed doped emitter can be thicker to eliminate the emitter depletion effect without compromising the short-wavelength-absorption-induced current loss. As a result, V_{oc} and fill factor can be improved. The back junction also provides more flexibility for tuning the p-type doped emitter work function, thus allowing a better work function matching between the emitter layer and the corresponding TCO layer. Hence, it is possible to select a more optimal back TCO material without being limited by its transmission properties. The back location of the junction also means that the solar cell is less affected by the higher-energy excess carrier recombination at the junction because the back junction is mostly impacted by longer-wavelength, lower-energy absorption.

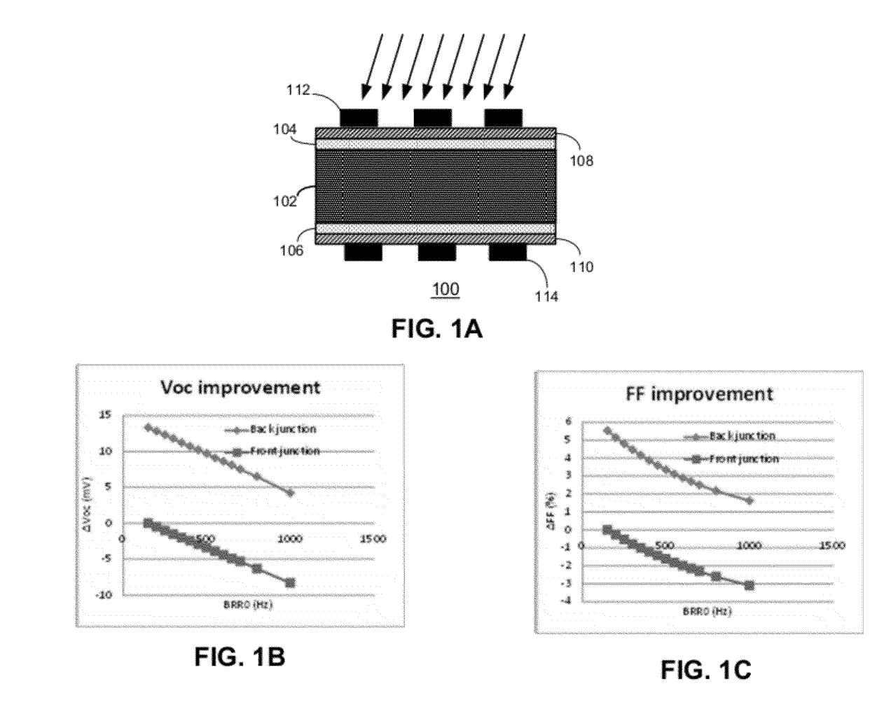

FIG. 1A presents a diagram illustrating an exemplary back junction solar cell with tunneling oxide, in accordance with an embodiment of the present invention. Back junction solar cell 100 includes a substrate 102; ultra-thin oxide layers 104 and 106 covering the front and back surfaces of substrate 102, respectively; a front surface field (FSF) layer 108; an emitter layer 110; a front electrode 112; and a back electrode 114. The arrows indicate the incoming sunlight.

As discussed previously, compared with conventional front junction solar cells, the minority carrier density of the back junction solar cells is lower, which results in a lowered junction recombination, thus giving a higher V_{oc} and a larger fill factor (FF). Moreover, a thicker emitter layer also leads to further reduced carrier depletion even without a complete matching of the work functions, thus further improving V_{oc} and FF. FIG. 1B presents a diagram illustrating the improvement of V_{oc} for the back junction solar cells over the front junction solar cells, in accordance with an embodiment of the present invention. Note that, in FIG. 1B, BRR0 is the intrinsic recombination rate for the Si wafer. FIG. 1C presents a diagram illustrating the improvement of FF for the back junction solar cells over the front junction solar cells, in accordance with an embodiment of the present invention. One can see that, with optimized emitter thickness and work function matching to the TCO layer, significant improvements of V_{oc} and FF can be observed for the back junction solar cells.

### Fabrication Method I

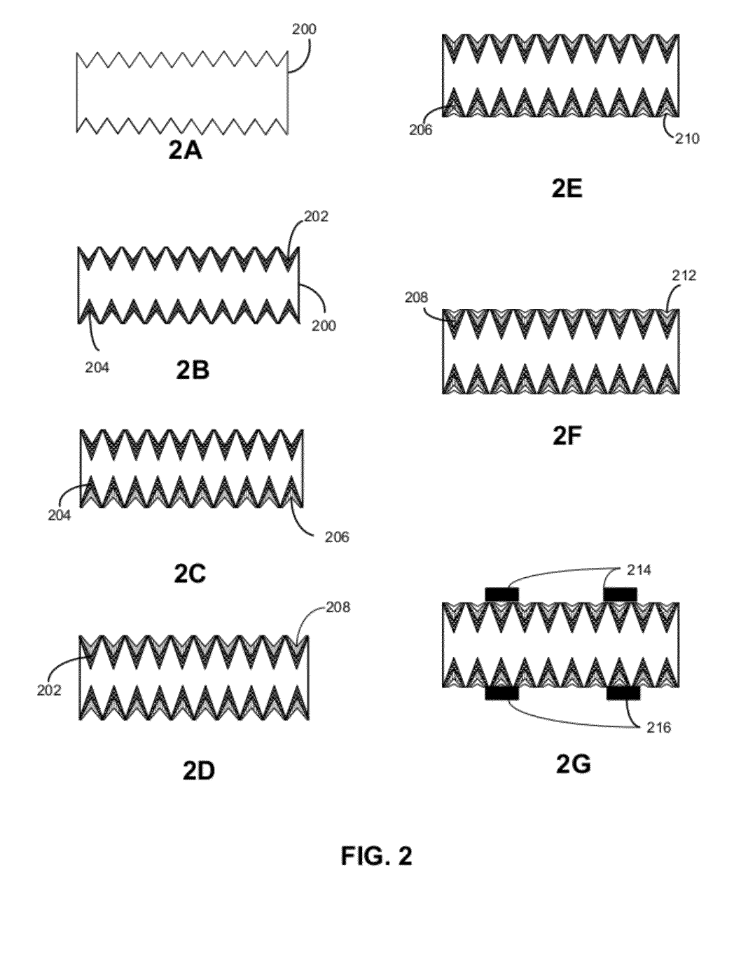

Either n- or p-type doped high-quality solar-grade silicon (SG-Si) wafers can be used to build the back junction solar cell. In one embodiment, an n-type doped SG-Si wafer is selected. FIG. 2 presents a diagram illustrating the process of fabricating a back junction solar cell with tunneling oxide, in accordance with an embodiment of the present invention.

In operation 2A, an SG-Si substrate 200 is prepared. The thickness of SG-Si substrate 200 can range between 80 and 200 μm. In one embodiment, the thickness of SG-Si substrate 200 rages between 90 and 120 μm. The resistivity of SG-Si substrate 200 is typically in, but not limited to, the range between 1 Ohm-cm and 10 Ohm-cm. In one embodiment, SG-Si substrate 200 has a resistivity between 1 Ohm-cm and 2 Ohm-cm. The preparation operation includes typical saw damage etching that removes approximately 10 μm of silicon and surface texturing. The surface texture can have various patterns, including but not limited to: hexagonal-pyramid, inverted pyramid, cylinder, cone, ring, and other irregular shapes. In one embodiment, the surface texturing operation results in a random pyramid textured surface. Afterwards, SG-Si 200 substrate goes through extensive surface cleaning.

In operation 2B, a thin layer of high-quality (with Dᵢₜ less than 1×10¹¹/cm²) dielectric material is deposited on the front and back surfaces of SG-Si substrate 200 to form front and back passivation/tunneling layers 202 and 204, respectively. In one embodiment, only the back surface of SG-Si substrate 200 is deposited with a thin layer of dielectric material. Various types of dielectric materials can be used to form the passivation/tunneling layers, including, but not limited to: silicon oxide (SiOₓ), hydrogenerated SiOₓ, silicon nitride (SiNₓ), hydrogenerated SiNₓ, aluminum oxide (AlOₓ), silicon oxynitride (SiON), and hydrogenerated SiON. In addition, various deposition techniques can be used to deposit the passivation/tunneling layers, including, but not limited to: thermal oxidation, atomic layer deposition, wet or steam oxidation, low-pressure radical oxidation, plasma-enhanced chemical-vapor deposition (PECVD), etc. The thickness of tunneling/passivation layers 202 and 204 can be between 1 and 50 angstroms. In one embodiment, the thickness of tunneling/passivation layers 202 and 204 is between 1 and 15 angstroms. Note that the well-controlled thickness of the tunneling/passivation layers ensures good tunneling and passivation effects.

In operation 2C, a layer of hydrogenerated, graded-doping a-Si having a doping type opposite to that of substrate 200 is deposited on the surface of back passivation/tunneling layer 204 to form emitter layer 206. As a result, emitter layer 206 is situated on the backside of the solar cell facing away from the incident sunlight. Note that, if SG-Si substrate 200 is n-type doped, then emitter layer 206 is p-type doped, and vice versa. In one embodiment, emitter layer 206 is p-type doped using boron as dopant. SG-Si substrate 200, back passivation/tunneling layer 204, and emitter layer 206 form the hetero-tunneling back junction. The thickness of emitter layer 206 is between 1 and 20 nm. Note that an optimally doped (with doping concentration varying between 1×10¹⁵/cm³ and 5×10²⁰/cm³) and sufficiently thick (at least between 3 nm and 20 nm) emitter layer is necessary to ensure a good ohmic contact and a large built-in potential. In one embodiment, the region within emitter layer 206 that is adjacent to front passivation/tunneling layer 202 has a lower doping concentration, and the region that is away from front passivation/tunneling layer 202 has a higher doping concentration. The lower doping concentration ensures minimum defect density at the interface between back passivation/tunneling layer 204 and emitter layer 206, and the higher concentration on the other side prevents emitter layer depletion. The work function of emitter layer 206 can be tuned to better match that of a subsequently deposited back transparent conductive oxide (TCO) layer to enable larger V_{oc} and a higher fill factor. In addition to a-Si, it is also possible to use other material, including but not limited to: one or more wide-bandgap semiconductor materials and polycrystalline Si, to form emitter layer 206.

In operation 2D, a layer of hydrogenerated, graded-doping a-Si having a doping type same as that of substrate 200 is deposited on the surface of front passivation/tunneling layers 202 to form front surface field (FSF) layer 208. Note that, if SG-Si substrate 200 is n-type doped, then FSF layer 208 is also n-type doped, and vise versa. In one embodiment, FSF layer 208 is n-type doped using phosphorous as dopant. SG-Si substrate 200, front passivation/tunneling layer 202, and FSF layer 208 form the front surface high-low homogenous junction that effectively passivates the front surface. In one embodiment, the thickness of FSF layer 208 is between 1 and 30 nm. In one embodiment, the doping concentration of FSF layer 208 varies from 1×10¹⁵/cm³ to 5×10²⁰/cm³. In addition to a-Si, it is also possible to use other material, including but not limited to: wide-bandgap semiconductor materials and polycrystalline Si, to form FSF layer 208.

In operation 2E, a layer of TCO material is deposited on the surface of emitter layer 206 to form a back-side conductive anti-reflection layer 210, which ensures a good ohmic contact. Examples of TCO include, but are not limited to: indium-tin-oxide (ITO), indium oxide (InO), indium-zinc-oxide (IZO), tungsten-doped indium-oxide (IWO), tin-oxide (SnOₓ), aluminum doped zinc-oxide (ZnO:Al or AZO), Zn—In—O (ZIO), gallium doped zinc-oxide (ZnO:Ga), and other large bandgap transparent conducting oxide materials. The work function of back-side TCO layer 210 can be tuned to better match that of emitter layer 206.

In operation 2F, front-side TCO layer 212 is formed on the surface of FSF layer 208. Front-side TCO layer 212 forms a good anti-reflection coating to allow maximum transmission of sunlight into the solar cell.

In operation 2G, front-side electrode 214 and back-side electrode 216 are formed on the surfaces of TCO layers 212 and 210, respectively. In one embodiment, front-side electrode 214 and back-side electrode 216 include Ag finger grids, which can be formed using various techniques, including, but not limited to: screen printing of Ag paste, inkjet or aerosol printing of Ag ink, and evaporation. In a further embodiment, front-side electrode 214 and/or back-side electrode 216 can include Cu grid formed using various techniques, including, but not limited to: electroless plating, electro plating, sputtering, and evaporation.

### Fabrication Method II

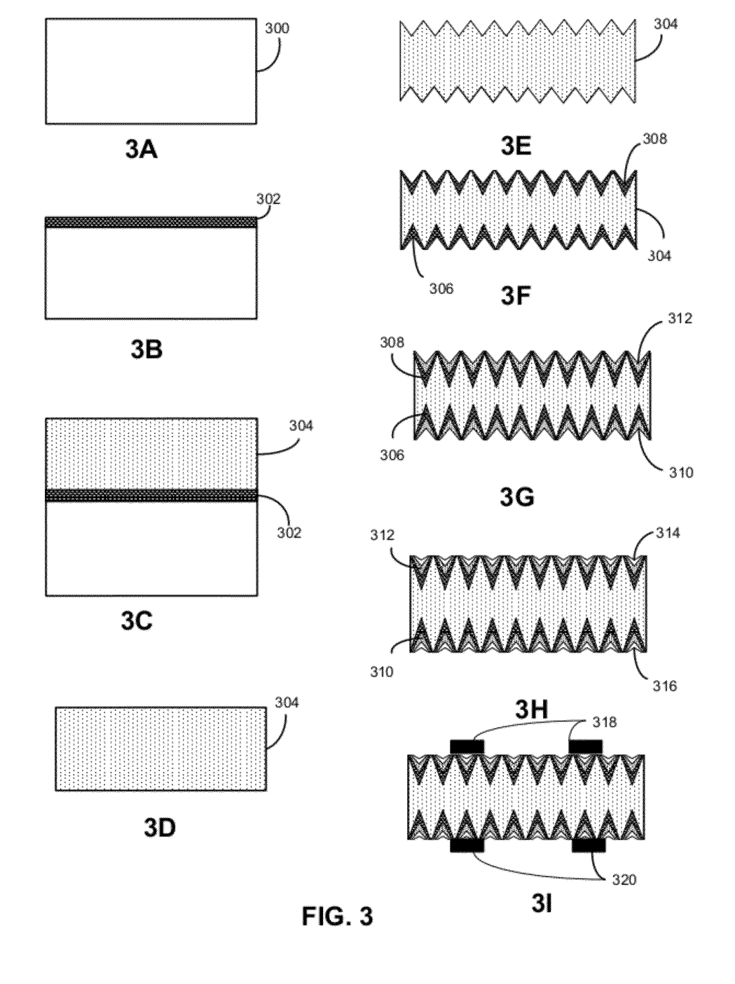

FIG. 3 presents a diagram illustrating the process of fabricating a back junction solar cell with tunneling oxide, in accordance with an embodiment of the present invention. The fabrication process is similar to the one shown in FIG. 2 except that, instead of using an SG-Si wafer as a base layer, the base layer of the back junction solar cell fabricated in FIG. 3 is a layer of epitaxially grown c-Si.

In operation 3A, an SG-Si substrate 300 is prepared using a process similar to that of operation 2A, except that no surface texturing is formed.

In operation 3B, a thin layer of heavily doped c-Si, layer 302, is epitaxially grown on SG-Si substrate 300. In one embodiment, heavily doped c-Si epitaxial (EPI) layer 302 is formed using a chemical-vapor-deposition (CVD) epitaxial process. Various types of Si compounds, such as SiH₄, SiH₂Cl₂, and SiHCl₃, can be used as a precursor in the CVD process to form heavily doped c-Si EPI layer 302. In one embodiment, SiHCl₃ (TCS) is used due to its abundance and low cost. The thickness of heavily doped c-Si EPI layer 302 can be between 1 μm and 5 μm. The doping type of heavily doped c-Si EPI layer 302 is the same as the doping type of SG-Si substrate 300. In one embodiment, heavily doped c-Si EPI layer 302 is n-type doped. The doping concentration of heavily doped c-Si EPI layer 302 can be between 1×10¹⁷/cm³ and 1×10²⁰/cm³. The doping level should not exceed a maximum limit, which may cause misfit dislocations in the film. Heavily doped c-Si EPI layer 302 can act as a back surface field (BSF), an impurity barrier, and a contaminant getter layer for reducing electron-hole recombination at the surface of the subsequently grown base layer.

In operation 3C, a layer of lightly doped c-Si is epitaxially grown on heavily doped c-Si EPI layer 302 to form a base layer 304. The process used for the growth of base layer 304 is similar to the one used for the growth of heavily doped c-Si EPI layer 302. In one embodiment, a CVD EPI process is used to form base layer 304. The thickness of base layer 304 can be between 20 μm and 100 μm. The conductive doping type of base layer 304 is the same as the doping type of SG-Si substrate 200 and heavily doped c-Si EPI layer 302. In one embodiment, base layer 304 is n-type doped, which can provide better carrier lifetime, higher V_{oc}, and higher solar cell efficiency. The doping concentration of base layer 304 can be between 1×10¹⁵/cm³ and 1×10¹⁷/cm³.

After EPI growth of base layer 304, in operation 3D, SG-Si substrate 300 and heavily doped c-Si EPI layer 302 are removed. Various techniques can be used to remove SG-Si substrate 300 and heavily doped c-Si EPI layer 302, including, but not limited to: mechanical grinding, chemical wet etching, dry etching, and chemical mechanical polishing. In one embodiment, a mechanical backgrinding method is used to remove SG-Si substrate 300 and heavily doped c-Si EPI layer 302. Subsequently, a wet chemical etching process is used to remove all backgrind damage which may result in increased minority-carrier recombination, thus degrading the solar cell performance. Solutions used in the wet chemical etching include, but are not limited to: sodium hydroxide (NaOH), tetramethylammonium hydroxide (TMAH), and a mixture of nitric acid and hydrofluoric acid (HNO₃:HF).

In operation 3E, the front and back surfaces of base layer 304 are textured to maximize light absorption inside the solar cell, thus further enhancing solar cell conversion efficiency. The shapes of the surface texture can be pyramids or inverted pyramids, which are randomly or regularly distributed on the front and back surfaces of base layer 304.

The rest of the fabrication process is similar to the one shown in FIG. 2. In operation 3F, back and front passivation/tunneling layers 306 and 308 are formed using a process similar to operation 2B.

In operation 3G, emitter layer 310 and FSF layer 312 are formed using a process similar to the one used in operations 2C and 2D.

In operation 3H, front and back TCO layers 314 and 316 are formed using a process similar to the one used in operations 2E and 2F.

In operation 3I, front and back electrodes 318 and 320 are formed using a process similar to the one used in operation 2G.

### Fabrication Method III

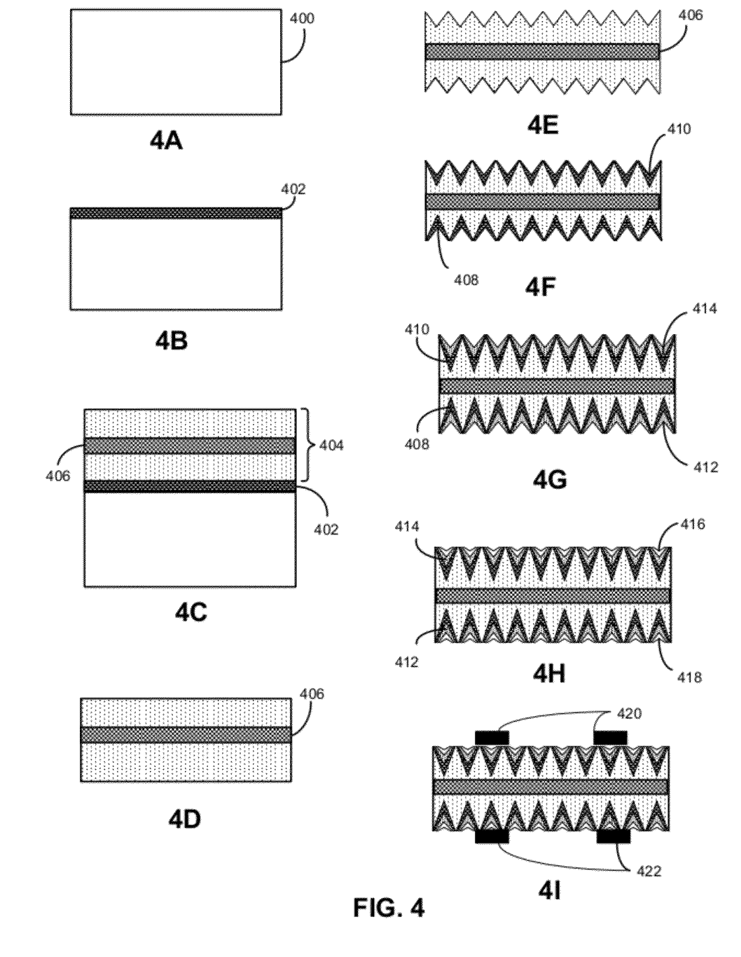

FIG. 4 presents a diagram illustrating the process of fabricating a back junction solar cell within tunneling oxide, in accordance with an embodiment of the present invention. The fabrication process is similar to the one shown in FIG. 3, except that the epitaxially formed Si base layer now has a graded doping profile.

In operation 4A, an SG-Si substrate 400 is prepared using a process similar to that of operation 3A.

In operation 4B, a thin layer of heavily doped c-Si, layer 402, is epitaxially grown on SG-Si substrate 400 using a process similar to that of operation 3B.

In operation 4C, a layer of c-Si with graded doping is epitaxially grown on heavily doped c-Si EPI layer 402 to form a base layer 404. The doping concentration of base layer 404 is between 1×10¹⁴/cm³ and 1×10¹⁸/cm³, with the region adjacent to heavily doped c-Si EPI layer 402 having a lower doping concentration and the opposite side having a higher doping concentration. Such a doping profile results in an electric field that allows the generated minority carriers to drift toward the junction, thus increasing the J_{sc}. The thickness of graded-doped base layer 404 can be between 20 μm and 100 μm. In one embodiment, a thin layer of intrinsic EPI c-Si (layer 406) is inserted within graded-doped base layer 404. In one embodiment, intrinsic EPI c-Si layer 406 is placed in the middle of graded-doped base layer 404. The thickness of intrinsic EPI c-Si layer 406 can be between 1 and 10 nm. The insertion of intrinsic EPI c-Si layer 406 ensures better film quality of graded-doped base layer 404 because it limits defect propagation and lattice mismatch during the EPI growth of base layer 404. Note that intrinsic EPI c-Si layer 406 can be deposited at any point during the growth of graded-doped base layer 404 by changing the gas flow into the epitaxial chamber.

The rest of the fabrication process is similar to the one shown in FIG. 3. In operation 4D, SG-Si substrate 400 and heavily doped c-Si EPI layer 402 are removed using a process similar to operation 3D. In operation 4E, the front and back surfaces of base layer 404 are textured using a process similar to operation 3E. In operation 4F, back and front passivation/tunneling layers 408 and 410 are formed using a process similar to operation 3F. In operation 4G, emitter layer 412 and FSF layer 414 are formed using a process similar to the one used in operation 3G. In operation 4H, front and back TCO layers 416 and 418 are formed using a process similar to the one used in operation 3H. In operation 41, front and back electrodes 420 and 422 are formed using a process similar to the one used in operation 31.

### Fabrication Method IV

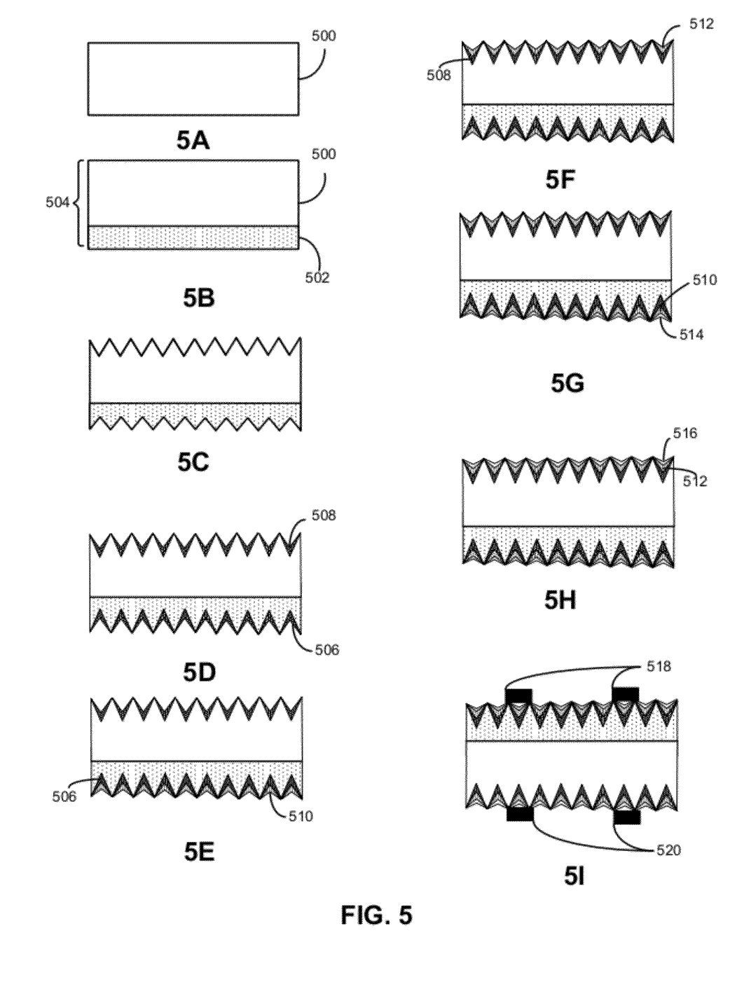

FIG. 5 presents a diagram illustrating the process of fabricating a back junction solar cell with tunneling oxide, in accordance with an embodiment of the present invention. The fabrication process is similar to the one shown in FIG. 2, except that an epitaxially formed c-Si layer is deposited on the SG-Si substrate to form a composite base.

In operation 5A, an SG-Si substrate 500 is prepared using a process similar to that of operation 2A, except that no surface texturing is formed.

In operation 5B, a thin layer of c-Si is epitaxially grown on the backside of SG-Si substrate 500 to form an enhancing layer 502. SG-Si substrate 500 and enhancing layer 502 together form a composite base layer 504. The doping type of enhancing layer 502 is similar to that of SG-Si substrate 500. In one embodiment, enhancing layer 502 is n-type doped. In addition, enhancing layer 502 can either be uniformly doped or graded doped. In one embodiment, enhancing layer 502 is uniformly doped with a uniform sheet resistance of 0.5 ohm-cm. In one embodiment, enhancing layer 502 is graded doped with sheet resistance varying between 0.2 ohm-cm and 1 ohm-cm. The thickness of enhancing layer 502 can be between 0.5 μm and 2 μm. Note that, compared with the solar cells fabricated in FIGS. 3 and 4, the thickness of enhancing layer 502, which is an EPI c-Si layer, is much thinner than EPI base layers 304 and 404, whose thickness can be greater than 20 μm. Such a thin EPI layer can be easily manufactured at a lower cost. By combining SG-Si substrate 500 (which can be a cheaper polysilicon substrate and can be used as an absorber layer) and thin EPI enhancing layer 502 (whose characteristics can be carefully engineered during EPI growth) as a composite base layer, we can achieve the goal of lowering manufacture cost and improving performance at the same time.

The rest of the fabrication process is similar to the one shown in FIG. 2. In operation 5C, the front and back surfaces of composite base layer 504 are textured using a process similar to operation 2A. In operation 5D, back and front passivation/tunneling layers 506 and 508 are formed using a process similar to operation 2B. In operation 5E, an emitter layer 510 is deposited on the surface of back passivation/tunneling layer 506 using a process similar to operation 2C. In operation 5F, a FSF layer 512 is deposited on the surface of front passivation/tunneling layer 508 using a process similar to operation 2D. In operation 5G, a back TCO layer 514 is deposited on the surface of emitter layer 510 using a process similar to operation 2E. In operation 5H, a front TCO layer 516 is deposited on the surface of FSF layer 512 using a process similar to operation 2F. In operation 51, front and back electrodes 518 and 520 are formed using a process similar to the one used in operation 2G.

The foregoing descriptions of various embodiments have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention.

What is claimed is:

1. A method for fabricating a back junction solar cell, comprising:
obtaining a base layer for the solar cell;
forming a quantum-tunneling-barrier (QTB) layer at a backside of the base layer facing away from incident light;
forming an emitter layer underneath the QTB layer, wherein a doping type of the emitter layer is opposite to a doping type of the base layer;
forming a front surface field (FSF) layer above the base layer;
forming a front-side electrode above the FSF layer; and
forming a back-side electrode underneath the emitter layer.

2. The method of claim 1, wherein the base layer comprises at least one of:
a mono-crystalline silicon wafer; and
an epitaxially grown crystalline-Si (c-Si) thin film.

3. The method of claim 2, wherein the epitaxially grown c-Si thin film's doping profile is modulated.

4. The method of claim 1, wherein the QTB layer comprises at least one of:
silicon oxide (SiOₓ);
hydrogenerated SiOₓ;
silicon nitride (SiNₓ);
hydrogenerated SiNₓ;
aluminum oxide (AlOₓ);
silicon oxynitride (SiON); and
hydrogenerated SiON.

5. The method of claim 1, wherein the QTB layer has a thickness between 1 and 50 angstroms.

6. The method of claim 1, wherein the QTB layer is formed using at least one of the following techniques:
thermal oxidation;
atomic layer deposition;
wet or steam oxidation;
low-pressure radical oxidation; and
plasma-enhanced chemical-vapor deposition (PECVD).

7. The method of claim 1, further comprising forming a transparent conductive oxide (TCO) layer on surface of the emitter layer, the FSF layer, or both.

8. The method of claim 7, wherein the TCO layer comprises at least one of:
indium-tin-oxide (ITO);
indium oxide (InO);
indium-zinc-oxide (IZO);
tungsten-doped indium-oxide (IWO);
tin-oxide (SnOₓ);
aluminum doped zinc-oxide (ZnO:Al or AZO); and
gallium doped zinc-oxide (ZnO:Ga).

9. The method of claim 1, wherein the emitter layer and/or the FSF layer comprise at least one of:
amorphous-Si (a-Si);
polycrystalline Si; and
one or more wide bandgap semiconductor materials.

10. The method of claim 9, wherein the emitter layer and/or the FSF layer comprise a graded-doped amorphous-Si (a-Si) layer with a doping concentration ranging between 1×10¹⁵/cm³ and 5×10²⁰/cm³.

11. The method of claim 1, further comprising forming a front QTB layer at a frontside of the base layer facing the incident sunlight.

12. A back junction solar cell, comprising:
a base layer;
a quantum-tunneling-barrier (QTB) layer situated below the base layer facing away from incident light;
an emitter layer situated below the QTB layer;
a front surface field (FSF) layer situated above the base layer;
a front-side electrode situated above the FSF layer; and
a back-side electrode situated below the emitter layer.

13. The solar cell of claim 12, wherein the base layer comprises at least one of:
a mono-crystalline silicon wafer; and
an epitaxially grown crystalline-Si (c-Si) thin film.

14. The solar cell of claim 13, wherein the epitaxially grown c-Si thin film's doping profile is modulated.

15. The solar cell of claim 12, wherein the QTB layer comprises at least one of:
silicon oxide (SiOₓ);
hydrogenerated SiOₓ;
silicon nitride (SiNOₓ);
hydrogenerated SiNₓ;
aluminum oxide (AlOₓ);
silicon oxynitride (SiON); and
hydrogenerated SiON.

16. The solar cell of claim 12, wherein the QTB layer has a thickness between 1 and 50 angstroms.

17. The solar cell of claim 12, wherein the QTB layer is formed using at least one of the following techniques:
thermal oxidation;
atomic layer deposition;
wet or steam oxidation;
low-pressure radical oxidation; and
plasma-enhanced chemical-vapor deposition (PECVD).

18. The solar cell of claim 12, further comprising at least one of:
a first transparent conductive oxide (TCO) layer situated below the emitter layer; and
a second TCO layer situated above the FSF layer.

19. The solar cell of claim 18, wherein the first and second TCO layers comprises at least one of:
indium-tin-oxide (ITO);
indium oxide (InO);
indium-zinc-oxide (IZO);
tungsten-doped indium-oxide (IWO);
tin-oxide (SnOx);
aluminum doped zinc-oxide (ZnO:Al or AZO); and
gallium doped zinc-oxide (ZnO:Ga).

20. The solar cell of claim 12, wherein the emitter layer and/or the FSF layer comprise at least one of:
amorphous-Si (a-Si);
polycrystalline Si; and
one or more wide bandgap semiconductor materials.

21. The solar cell of claim 20, wherein the emitter and/or the surface field layer comprise a graded-doped amorphous-Si (a-Si) layer with a doping concentration ranging between 1×10¹⁵/cm³ and 5×10²⁰/cm³.

22. The solar cell of claim 12, further comprising a front QTB layer situated between the FSF layer and the base layer.
